(19) United States
(12) Patent Application Publication
(10) Pub. No.: US 2012/0242593 A1
(43) Pub. Date: Sep. 27, 2012

(54) PIEZOELECTRIC VIBRATION MODULE AND TOUCH SCREEN USING THE SAME

(75) Inventors: Jae Kyung Kim, Gyunggi-do (KR); Dong Sun Park, Seoul (KR); Yeon Ho Son, Gyunggi-do (KR)

(73) Assignee: SAMSUNG ELECTRO-MECHANICS CO.,LTD., Gyunggi-do (KR)

(21) Appl. No.: 13/213,009

(22) Filed: Aug. 18, 2011

(30) Foreign Application Priority Data
Mar. 23, 2011 (KR) 1020110026016

(51) Int. Cl. G06F 3/041; H01L 41/09

(52) U.S. Cl. 345/173; 310/323.01

(57) ABSTRACT

Disclosed herein are a piezoelectric vibration module and a touch screen using the same. In the piezoelectric vibration module, a mass body is attached to a central portion of a vibration bar, thereby making it possible to maximize the amplitude of the piezoelectric vibration module, and a groove is formed in the vibration bar to provide elasticity and flexibility to the piezoelectric vibration module, thereby making it possible to maximize vibratory force of the piezoelectric vibration module. In the touch screen, the piezoelectric vibration module is attached to a lower surface of an image display part of the touch screen, thereby making it possible to directly transfer vibratory force generated in the piezoelectric vibration module to an input unit.

### CROSS REFERENCE TO RELATED APPLICATION

This application claims the benefit of Korean Patent Application No. 10-2011-0026016, filed on Mar. 23, 2011, entitled “Piezoelectric Vibration Module And Touch Screen Using The Same”, which is hereby incorporated by reference in its entirety into this application.

### BACKGROUND OF THE INVENTION

1. Technical Field

The present invention relates to a piezoelectric vibration module and a touch screen using the same.

2. Description of the Related Art

In accordance with the development of a mobile communication technology, terminals such as cellular phones, personal digital assistances (PDAs), and navigations can serve as a unit that simply displays character information as well as a unit for providing various and complex multi-media such as audio, moving picture, radio internet web browser, or the like. Therefore, electronic information terminals having a limited size require a larger display screen, such that a display device using a touch screen has become prominent.

Meanwhile, in a portable electronic device such as a portable phone, a game machine, an e-book, or the like, a vibration function has been employed as various uses. Particularly, a vibration generating device performing the vibration function has been mounted in a mobile device using the touch screen such as the portable phone, or the like, such that it has been used as a receiving signal sensing function for a transmitting signal.

As the vibration generating device is used in the touch screen, the demand for a touch screen device allowing a user to immediately perceive feedback vibration for his/her touch input has increased.

FIG. 1 is a cross-sectional view showing a structure of a touch screen using a vibration generating device according to the prior art. A touch screen 10 according to the prior art is configured to include a touch screen panel 20, an image display part 30 attached to a lower surface of the touch screen panel 20, and a vibration generating device 50 attached to an inside of an outer set 40 accommodating the touch screen panel 20. As a to scheme of generating vibration according to the prior art, a scheme of mounting the vibration generating device 50 such as a vibration motor, a vibration actuator, or the like, in an inner portion of the touch screen 10 of a cellular phone, etc., has been used. Here, the vibration generating device 50 has been mounted inside the outer set 40 of the touch screen 10.

In the touch screen 10, since the vibration generating device 50 has been mounted inside the outer set 40, when a signal input part is operated using a finger or a touch pen, vibratory force of the vibration generating device 50 has been not properly transferred to a part of the touch screen panel 20 contacting the input unit.

Meanwhile, as the vibration generating device 50 according to the prior art, a vibration motor, a vibration actuator, or the like, has been mainly used. The vibration generating device 50 according to the prior art had a difficulty in being designed to have a thin thickness, such that it had a technical problem in being directly attached to a lower surface of the image display part 30.

### SUMMARY OF THE INVENTION

The present invention has been made in an effort to provide a piezoelectric vibration module having a structure capable of maximizing vibratory force and also provide a touch screen capable of directly transferring vibratory force generated in the piezoelectric vibration module to an input unit by applying the piezoelectric vibration module to the touch screen.

According to a first preferred embodiment of the present invention, there is provided a piezoelectric vibration module including: a vibration bar; and a pair of piezoelectric bodies formed at both sides on one surface of the vibration bar based on a central portion of one surface of the vibration bar.

The vibration bar may have a bar shape, such that it is vertically reciprocatingly vibrated in a thickness direction thereof by the shrinkage and expansion of the piezoelectric body.

The piezoelectric vibration module may further include a mass body attached to the central portion of the vibration bar.

The piezoelectric vibration module may further include grooves formed at both ends of the vibration bar in a length direction thereof so as to penetrate through the vibration bar in a thickness direction thereof.

The vibration bar may be made of Invar.

The mass body may be formed to protrude to both sides of the vibration bar in a width direction thereof.

The mass body may be made of steel use stainless (SUS) or tungsten (W).

The piezoelectric vibration module may further include a mass body attached to the central portion of the vibration bar and grooves formed at both ends of the vibration bar in a length direction thereof, wherein a position of the piezoelectric body attached to one surface of the vibration bar is varied between the mass body and the groove.

According to a second preferred embodiment of the present invention, there is provided a touch screen using a piezoelectric vibration module, the touch screen including: a touch screen panel; an image display part attached to one surface of the touch screen panel; and the piezoelectric vibration module including a vibration bar and a pair of piezoelectric bodies formed at both sides on one surface of the vibration bar based on a central portion of one surface of the vibration bar and directly attached to one surface of the image display part.

The piezoelectric vibration module may further include adhesive parts formed on the other surface of the vibration bar, and the piezoelectric vibration module may be attached to the center of one surface of the image display part by the adhesive parts.

The piezoelectric vibration module may further include adhesive parts formed on the other surface of the vibration bar, and the piezoelectric vibration module may be attached to the edge of one surface of the image display part by the adhesive parts.

The piezoelectric vibration module may further include adhesive parts formed on sides of the vibration bar, and the piezoelectric vibration module may be attached to the center of one surface of the image display part by the adhesive parts.

The piezoelectric vibration module may further include adhesive parts formed on sides of the vibration bar, and the piezoelectric vibration module may be attached to the edge of one surface of the image display part by the adhesive parts.

The piezoelectric vibration module may further include a mass body attached to the central portion of the vibration bar.

The piezoelectric vibration module may further include grooves formed at both ends of the vibration bar in a length direction thereof so as to penetrate through the vibration bar in a thickness direction thereof.

The vibration bar may be made of Invar.

The mass body may be formed to protrude to both sides of the vibration bar in a width direction thereof.

The mass body may be made of steel use stainless (SUS) or tungsten (W).

The piezoelectric vibration module may further include a mass body attached to the central portion of the vibration bar and grooves formed at both ends of the vibration bar in a length direction thereof, wherein a position of the piezoelectric body attached to one surface of the vibration bar is varied between the mass body and the groove.

### BRIEF DESCRIPTION OF THE DRAWINGS

FIG. 1 is a cross-sectional view showing a structure of a touch screen using a vibration generating device according to the prior art;

FIGS. 2 to 6 are cross-sectional views and plan views showing a structure of a piezoelectric vibration module according to a preferred embodiment of the present invention;

FIG. 7 is a simulation view showing deformation amount for each position of a piezoelectric vibration module attached to an image display part;

FIG. 8 is a graph showing displacement of a piezoelectric vibration module according to frequency;

FIG. 9 is a cross-sectional view showing a structure of a touch screen using a piezoelectric vibration module according to the present invention; and

FIGS. 10 to 13 are views showing various attachment shapes of a piezoelectric vibration module attached to an image display part.

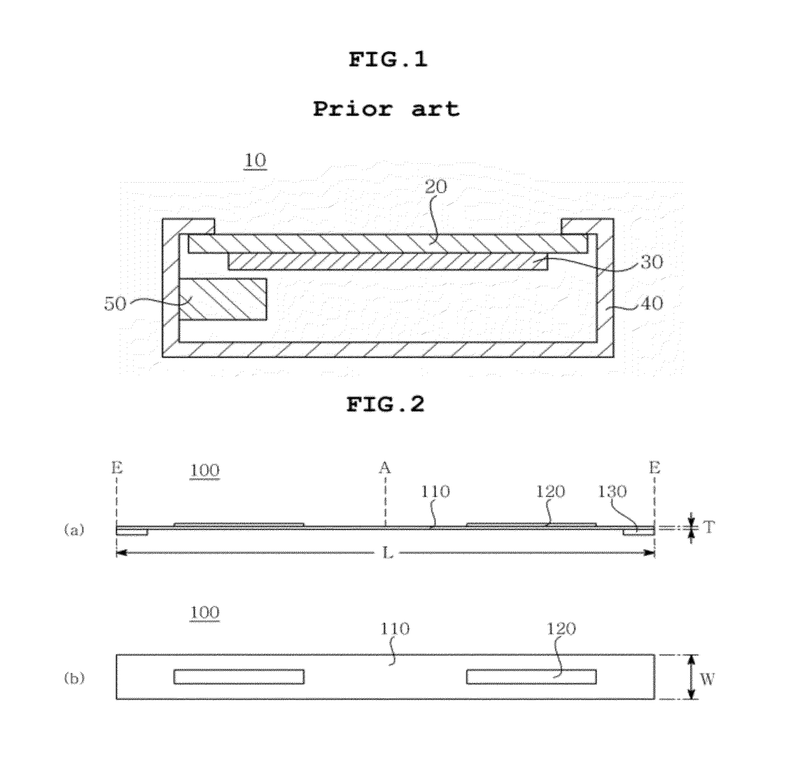

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

Piezoelectric Vibration Module

FIGS. 2 to 6 are views showing a structure of a piezoelectric vibration module according to a preferred embodiment of the present invention. Hereinafter, a piezoelectric vibration module 100 according to the present embodiment will be described with reference to FIGS. 2 to 6.

As shown in FIG. 2, the piezoelectric vibration module 100 according to a preferred embodiment of the present invention is configured to include a vibration bar 110, and a pair of piezoelectric bodies 120 formed at both sides on one surface of the vibration bar 110.

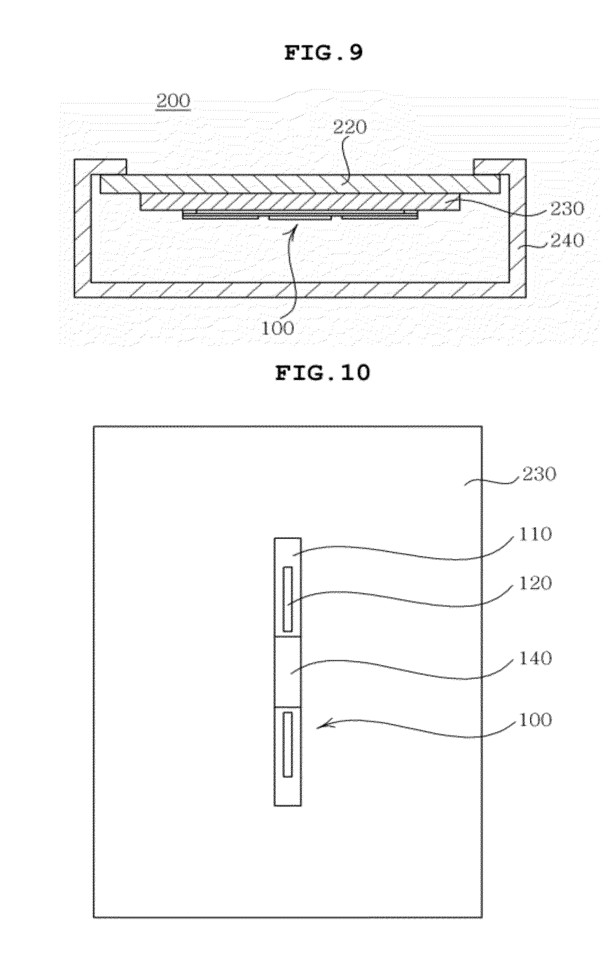

The vibration bar 110, which is a member subjected to the shrinkage/expansion movement of the piezoelectric body 120 to thereby generate vibration in the piezoelectric vibration module 100, has a predetermined length (L), width (W), and thickness (T). In the piezoelectric vibration motor according to the present invention, the vibration bar 110 is vertically reciprocatingly moved in a thickness T direction thereof, thereby transferring vibratory force to a contact member (for example, a slider, a rotor, or an image display part 230 (See FIG. 9)), or the like. Therefore, the vibration bar 110 has a bar shape elongated in a length (L) direction thereof in order to maximize the amplitude in the thickness (T) direction thereof.

Meanwhile, the vibration bar 110 is made of a metal having excellent elastic force in order to prevent fatigue failure thereof due to the reciprocating deformation thereof. Moreover, in order to reduce thermal stress generated due to a difference in coefficients of thermal expansion between the vibration bar 110 and the piezoelectric body 120, a material having a coefficient of thermal expansion similar to that of the piezoelectric body 120 is preferably selected as a material of the vibration bar 120. The vibration bar may be made of, for example, steel use stainless (SUS), Invar; however, a material of the vibration bar is not specifically limited.

The piezoelectric body 120 is shrunk/expanded by the application of a voltage and includes an electrode formed thereon. When a predetermined set voltage is applied to the electrode, the piezoelectric body 120 is flexurally vibrated while being shrunk or expanded, such that the vibration bar 110 is entirely driven vertically.

The piezoelectric body 120 configuring the piezoelectric vibration module 100 according to the present invention is formed on one surface of the vibration bar 110. Basically, each of a pair of piezoelectric bodies 120 is disposed at both sides based on a central portion A of the vibration bar 110 in a length (L) direction thereof. The piezoelectric bodies 120 may be formed in a single layer structure at both sides of the vibration bar 110. In addition, at least one piezoelectric body 120 may be stacked in a multi-layer structure. When the piezoelectric bodies 120 are stacked in the multi-layer structure, even though a low voltage is applied to the piezoelectric bodies 120, the driving force required for driving the piezoelectric vibration module 100 may be implemented. In addition, it is possible to form the piezoelectric bodies 120 in a single-layer structure on the vibration bar 110 and dispose the piezoelectric bodies 120 in parallel in a width (W) direction of the vibration bar 110. When the number of piezoelectric bodies 120 formed on the vibration bar 110 as described above increases, the entire vibratory force of the piezoelectric vibration module 100 increase.

Meanwhile, each of the piezoelectric bodies 120 may be positioned to be variable between a central portion A of the vibration bar 110 in a length direction thereof and one end E in the length direction thereof; however, is preferably positioned as closely as possible to the central portion A. This is the reason that when the piezoelectric body 120 is positioned at the center between the central portion A of the vibration bar 110 and one end E thereof, the magnitudes of each moment generated at both ends of the piezoelectric body 120 during shrinkage/expansion movement of the piezoelectric body 120 correspond to each other, thereby hindering the entire vertical reciprocating movement of the vibration bar.

Meanwhile, the piezoelectric body 120 may be made of a piezoelectric material such as a piezoelectric ceramic (PZT), a piezoelectric crystal, or the like.

Meanwhile, the vibration bar 110 may have adhesive parts 130 formed on the other surface thereof. The piezoelectric vibration module 100 is attached to a lower surface of an image display part 230 (See FIG. 9) to be described below by the adhesive parts 130. The adhesive part 130 may also be attached to a side of the vibration bar 110 according to a shape in which the piezoelectric vibration module 100 is attached to the image display part 230.

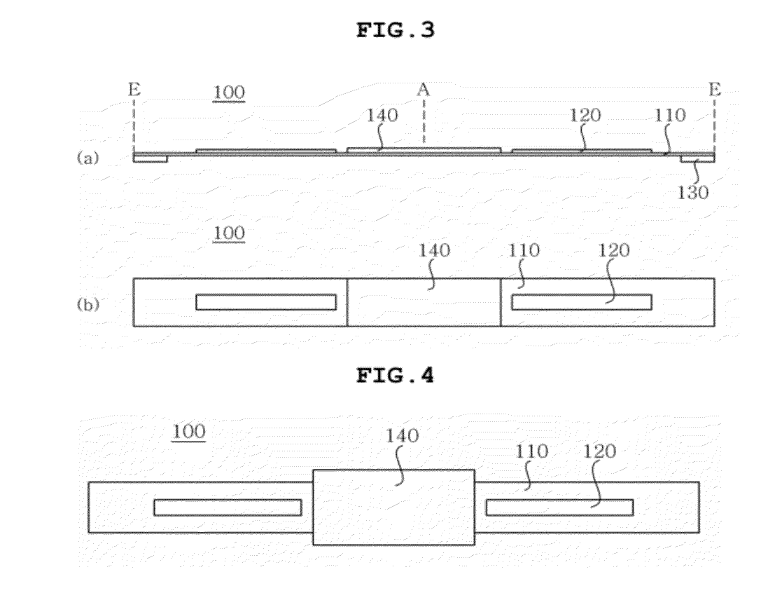

As shown in FIGS. 3 to 6, the piezoelectric vibration module 100 may further include a mass body 140. Since the mass of the piezoelectric vibration module 100 is concentrated on a point at which the driving displacement thereof is maximized, the mass body 140 is attached to the central portion of the vibration bar 110 to maximize mass eccentricity of the piezoelectric vibration module 100, thereby contributing to maximizing vibratory force of the piezoelectric vibration module 100. As a material of the mass body 140, a material having high density is preferably selected. Particularly, steel use stainless (SUS) or tungsten (W) may be used.

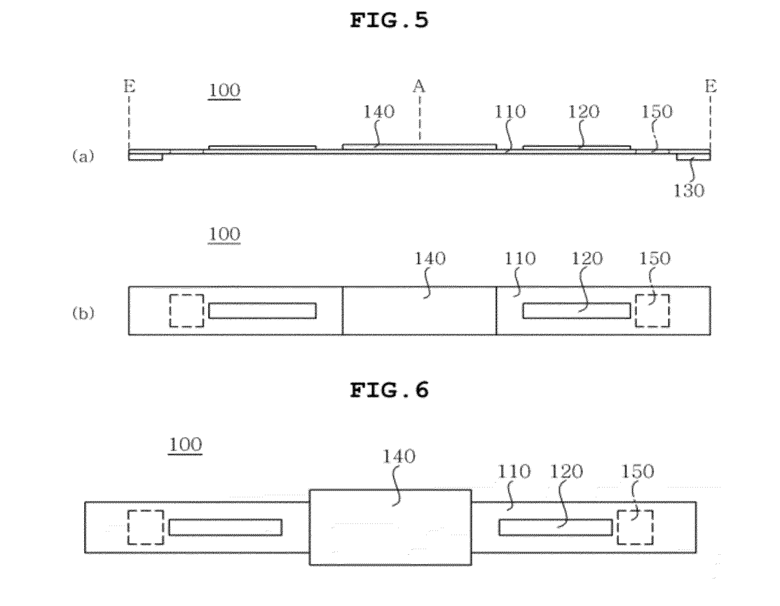

Meanwhile, the mass body 140 is formed to have a width narrower than that W of the vibration bar 110, such that it may be formed inside the vibration bar 110 (See FIG. 3 or FIG. 5). Furthermore, the mass body 140 may also be formed to protrude to both sides of the vibration bar 110 in a width (W) direction thereof (See FIG. 4 or FIG. 6). This is to increase mass of the mass body 140 attached to the central portion of the vibration bar 110, thereby improving vibratory force.

As shown in FIGS. 5 and 6, the piezoelectric vibration module 100 may further include grooves 150. The grooves 150 are formed at both ends of the vibration bar 110 in a length (L) direction thereof and penetrate through the vibration bar 110 in a thickness (T) direction thereof. When the groove 150 is formed, an elastic modulus (k) of the piezoelectric vibration module 100 is reduced, thereby making it possible to increase the amplitude of the vibration bar 110 with respect to the same input voltage.

Meanwhile, when the piezoelectric vibration module 100 configured of the vibration bar 110 and the piezoelectric bodies 120 is formed to further include the mass body 140 attached to the central portion of the vibration bar 110 and the grooves 150 formed at both ends of the vibration bar 110 in the length (L) direction thereof, arrangement positions of the piezoelectric bodies 120 attached to one surface of the vibration bar 110 may be varied between the mass body 140 and the grooves 150.

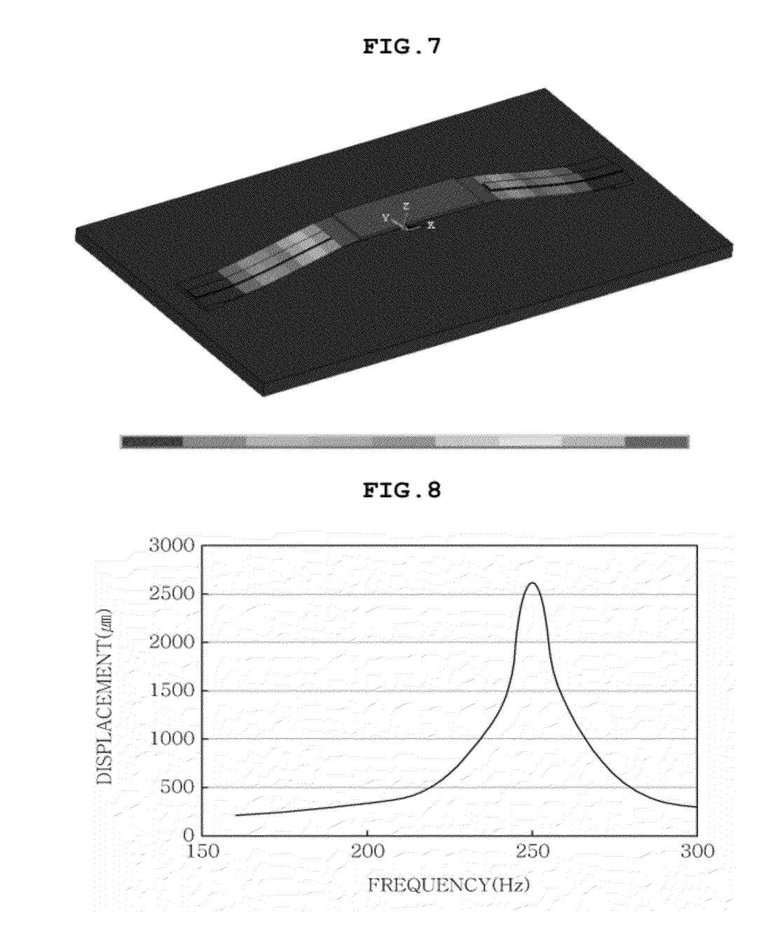

A structure of the piezoelectric vibration module 100 in which the mass body 140 is attached to the central portion of the vibration bar 110 and the piezoelectric bodies 120 are disposed at both sides based on the mass body 140 is to maximize the vibratory force. FIG. 7 is a simulation view showing deformation amount for each partial position of a piezoelectric vibration module 100 when the piezoelectric vibration module 100 is attached to an image display part 230 (See FIG. 9). The piezoelectric vibration module 100 has adhesive parts 130 (See FIG. 2) formed at both ends of the vibration bar 110 in a length (L) direction thereof, and is attached to the image display part 230 by the adhesive part 130. A bar shown at a lower side of FIG. 7 is shown with a dividing shadow according to the deformation amount thereof. The deformation amount (amplitude) becomes insignificant toward the left, and it becomes significant toward the right. As shown in FIG. 7, the vibration bar 110 has the deformation amount increased toward the central portion thereof, and has the maximum deformation amount at an area at which the mass body 140 is attached thereto. That is, the piezoelectric vibration module 100 according to the present invention has the mass body 140 disposed at a part at which the deformation amount of the vibration bar 110 is maximized, that is, the central portion of the vibration bar 110, thereby making it possible to maximize the vibratory force applied to the image display part 230. This is supported by the following vibratory force calculating equation:

G={m(x)ω2}/M

Where G indicates strength of vibratory force, M indicates the entire mass of the piezoelectric vibration module 100 and the image display part 230, m indicates the sum of masses of actually vibrating components in the piezoelectric vibration module 100, x indicates driving displacement (amplitude), and ω indicates frequency. That is, the mass body 140 having a predetermined mass is disposed at the central portion of the vibration bar 110 at which the driving displacement (x) of the piezoelectric vibration module 100 is maximized, thereby making it possible to maximize the vibratory force (G).

Meanwhile, FIG. 8 is a graph showing driving displacement according to frequency with respect to a piezoelectric vibration module 100 designed to have a specific specification. Here, the frequency of the piezoelectric vibration module 100 may be controlled by the following equation:

ω=(½π)*√(k/m)

Where k indicates an elastic modulus (k) of the piezoelectric vibration module 100, and m indicates mass of the piezoelectric vibration module 100. The values of k and m are controlled, thereby making it possible to design the piezoelectric vibration module 100 so as to have frequency at which it may be driven at the maximum displacement thereof.

Touch Screen Using Piezoelectric Vibration Module

FIG. 9 is a cross-sectional view showing a structure of a touch screen using a piezoelectric vibration module according to the present invention.

As shown in FIG. 9, a touch screen 200 using a piezoelectric vibration module 100 according to a preferred embodiment of the present invention is configured to include a touch screen panel 220, an image display part 230 attached to a lower surface of the touch screen panel 220, and a piezoelectric vibration module 100 including a vibration bar 110 and a pair of piezoelectric bodies 120 and directly attached to a lower surface of the image display part 230. The touch screen panel 220 is mounted in an outer set 240. The touch screen 200 according to the present invention uses a piezoelectric vibration module 100 disclosed in claims 1 to 9 and a detailed description of the disclosure for the piezoelectric vibration module 100, and the touch screen panel 220 and the image display part 230 includes structures in all shapes known in the prior art. Meanwhile, although FIGS. 10 to 13 show an image display part having a rectangular shape by way of example, a shape of the image display part 230 is not limited thereto. A touch screen 200 including an image display part 230 having a polygonal shape or a circular shape may be used.

An object of the present invention is to provide a touch screen 200 in which when the touch screen 200 is touched using an input unit, vibratory force generated in a piezoelectric vibration module 100 is directly transferred to the input unit. In the present invention, the piezoelectric vibration module 100 is directly attached to the lower surface of the image display part 230 in order to accomplish this object.

FIGS. 10 to 13 show various attachment shapes of a piezoelectric vibration module 100 attached to an image display part 230.

In a first preferred embodiment, the piezoelectric vibration module 100 further includes adhesive parts(not shown) formed on the other surface of the vibration bar 110 and is attached to the center of a lower surface of the image display part 230 by the adhesive parts(not shown) (See FIG. 10).

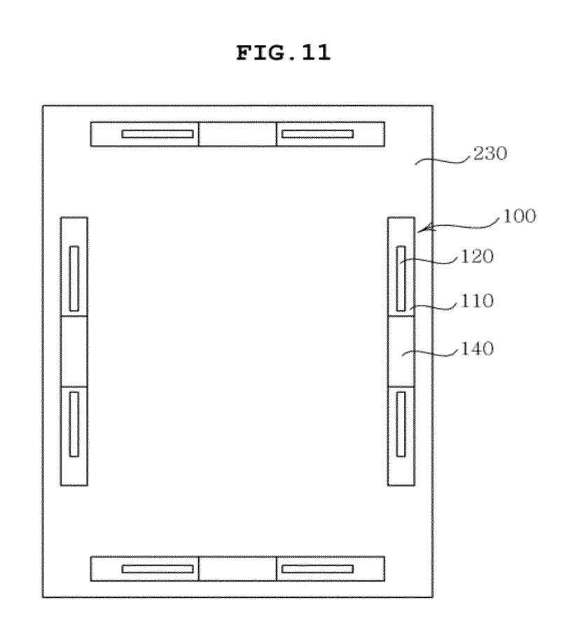

In a second preferred embodiment, the piezoelectric vibration module 100 further includes adhesive parts(not shown) formed on the other surface of the vibration bar 110 and is attached to the edge of a lower surface of the image display part 230 by the adhesive parts(not shown)(See FIG. 11). That is, when an image display part 230 having a polygonal shape is used, a plurality of piezoelectric vibration modules 100 may be attached to an inner side of at least one edge of the lower surface of the image display part 230, and when an image display part 230 having a circular shape is used, a plurality of piezoelectric vibration modules 100 may be attached to the lower surface of the image display part 230 so as to be spaced apart from each other by a predetermined interval.

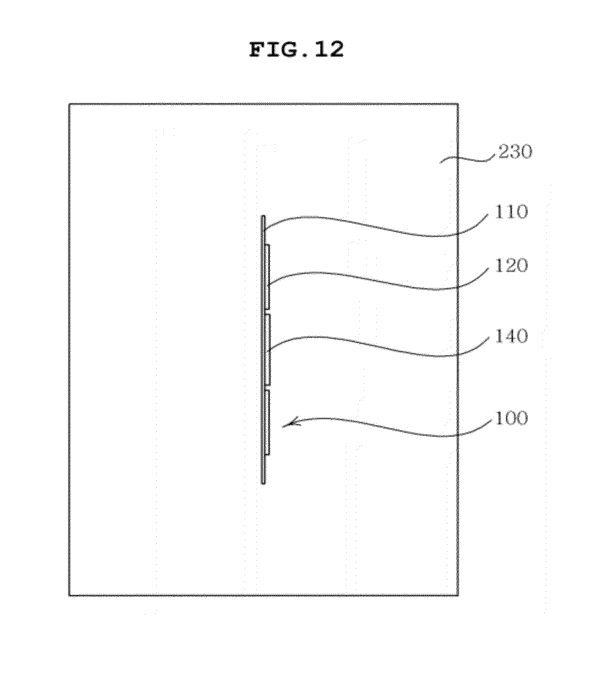

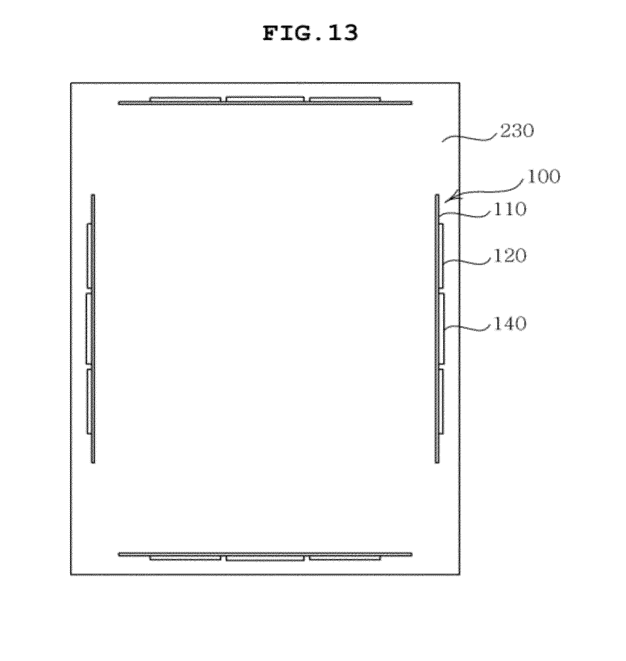

In a third preferred embodiment, the piezoelectric vibration module 100 further includes adhesive parts (not shown) formed on sides of the vibration bar 110 and is attached to the center (FIG. 12) or the edge (FIG. 13) of a lower surface of the image display part 230 by the adhesive parts 130. In this case, vertical driving of the piezoelectric vibration module 100 in a thickness (T) direction thereof induces vibration of the image display part 230 in a horizontal direction.

The piezoelectric vibration module 100 is attached to the image display part 230 in various shapes as described in the above-mentioned preferred embodiments, thereby making it possible to implement vibration of the image display part 230 in a horizontal direction or a vertical direction thereof.

According to the present invention, the mass body is attached to the central portion of the vibration bar, thereby making it possible to maximize the amplitude of the piezoelectric vibration module, and the groove is formed in the vibration bar to provide elasticity and flexibility to the piezoelectric vibration module, thereby making it possible to maximize vibratory force of the piezoelectric vibration module.

In addition, according to the present invention, the piezoelectric vibration module is attached to the lower surface of the image display part configuring the touch screen, thereby making it possible to directly transfer the vibratory force generated in the piezoelectric vibration module to an input unit.

Although the preferred embodiments of the present invention have been disclosed for illustrative purposes, they are for specifically explaining the present invention and thus a piezoelectric vibration module and a touch screen using the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A piezoelectric vibration module comprising:
a vibration bar; and
a pair of piezoelectric bodies formed at both sides on one surface of the vibration bar based on a central portion of one surface of the vibration bar.

2. The piezoelectric vibration module as set forth in claim 1, wherein the vibration bar has a bar shape, such that it is vertically reciprocatingly vibrated in a thickness direction thereof by the shrinkage and expansion of the piezoelectric body.

3. The piezoelectric vibration module as set forth in claim 1, further comprising a mass body attached to the central portion of the vibration bar.

4. The piezoelectric vibration module as set forth in claim 1, further comprising grooves formed at both ends of the vibration bar in a length direction thereof so as to penetrate through the vibration bar in a thickness direction thereof.

5. The piezoelectric vibration module as set forth in claim 1, wherein the vibration bar is made of Invar.

6. The piezoelectric vibration module as set forth in claim 3, wherein the mass body is formed to protrude to both sides of the vibration bar in a width direction thereof.

7. The piezoelectric vibration module as set forth in claim 3, wherein the mass body is made of steel use stainless (SUS) or tungsten (W).

8. The piezoelectric vibration module as set forth in claim 1, further comprising a mass body attached to the central portion of the vibration bar and grooves formed at both ends of the vibration bar in a length direction thereof, wherein a position of the piezoelectric body attached to one surface of the vibration bar is varied between the mass body and the groove.

9. A touch screen using a piezoelectric vibration module, the touch screen comprising:
a touch screen panel;
an image display part attached to one surface of the touch screen panel; and
the piezoelectric vibration module including a vibration bar and a pair of piezoelectric bodies formed at both sides on one surface of the vibration bar based on a central portion of one surface of the vibration bar and directly attached to one surface of the image display part.

10. The touch screen as set forth in claim 9, wherein the piezoelectric vibration module further includes adhesive parts formed on the other surface of the vibration bar, and
the piezoelectric vibration module is attached to the center of one surface of the image display part by the adhesive parts.

11. The touch screen as set forth in claim 9, wherein the piezoelectric vibration module further includes adhesive parts formed on the other surface of the vibration bar, and
the piezoelectric vibration module is attached to the edge of one surface of the image display part by the adhesive parts.

12. The touch screen as set forth in claim 9, wherein the piezoelectric vibration module further includes adhesive parts formed on sides of the vibration bar, and
the piezoelectric vibration module is attached to the center of one surface of the image display part by the adhesive parts.

13. The touch screen as set forth in claim 9, wherein the piezoelectric vibration module further includes adhesive parts formed on sides of the vibration bar, and
the piezoelectric vibration module is attached to the edge of one surface of the image display part by the adhesive parts.

14. The touch screen as set forth in claim 9, wherein the piezoelectric vibration module further includes a mass body attached to the central portion of the vibration bar.

15. The touch screen as set forth in claim 9, wherein the piezoelectric vibration module further includes grooves formed at both ends of the vibration bar in a length direction thereof so as to penetrate through the vibration bar in a thickness direction thereof.

16. The touch screen as set forth in claim 9, wherein the vibration bar is made of Invar.

17. The touch screen as set forth in claim 14, wherein the mass body is formed to protrude to both sides of the vibration bar in a width direction thereof.

18. The touch screen as set forth in claim 14, wherein the mass body is made of steel use stainless (SUS) or tungsten (W).

19. The touch screen as set forth in claim 9, wherein the piezoelectric vibration module further includes a mass body attached to the central portion of the vibration bar and grooves formed at both ends of the vibration bar in a length direction thereof, a position of the piezoelectric body attached to one surface of the vibration bar being varied between the mass body and the groove.
